(19) United States
(12) Patent Application Publication
(10) Pub. No.: US 2025/0327868 A1
(43) Pub. Date: Oct. 23, 2025

(54) POWER STORAGE AMOUNT ESTIMATING DEVICE

(71) Applicant: TOYOTA JIDOSHA KABUSHIKI KAISHA, Toyota-shi (JP)

(72) Inventor: Yuki SUGO, Seto-shi (JP)

(73) Assignee: TOYOTA JIDOSHA KABUSHIKI KAISHA, Toyota-shi (JP)

(21) Appl. No.: 19/000,731

(22) Filed: Dec. 24, 2024

(30) Foreign Application Priority Data
Apr. 19, 2024 (JP) 2024-068436

(51) Int. Cl. G01R 31/3835; G01R 31/3828; H01M 10/48; H02J 7/00

(52) U.S. Cl. CPC G01R 31/3835; G01R 31/3828; H01M 10/486; H02J 7/0048; H02J 7/007194

(57) ABSTRACT

A change in temperature during charging or discharging of the secondary battery is acquired, it is determined whether or not the change rate of the temperature change has varied, and when it is determined that the change rate of the temperature change has varied, it is estimated that the power storage amount of the secondary battery becomes a predetermined power storage amount.

### CROSS-REFERENCE TO RELATED APPLICATION

This application claims priority to Japanese Patent Application No. 2024-068436 filed on Apr. 19, 2024, incorporated herein by reference in its entirety.

### BACKGROUND

### 1. Technical Field

The present disclosure relates to a power storage amount estimating device for a secondary battery.

### 2. Description of Related Art

As a method for estimating a state of charge of a secondary battery, a method described in WO 2017/010475 described below is known. In WO 2017/010475 below, a map of a voltage change rate and a State Of Charge (SOC) is held for each charge rate and discharge rate, and a voltage step accompanying change in stages of an anode is detected in accordance with the voltage change rate.

### SUMMARY

The estimating method described in WO 2017/010475 can be applied when a charging current and a discharging current are constant, but is not applicable when the charging current and the discharging current change in accordance with the SOC as with vehicles.

Although a method using voltage detection is most accurate in order to detect behavior of stage-structure change of the anode, anode potential cannot be directly detected, and cathode potential needs to be estimated and then subtracted from closed circuit voltage (CCV) voltage for estimation thereof.

However, although the cathode potential can be made to be constant, the CCV voltage varies due to effects of changes in resistivity, polarization, and so forth, and accordingly the anode potential found by subtracting the cathode potential from the CCV voltage cannot be accurately estimated.

As described in WO 2017/010475 above, in order to catch change in the stage by potential change, the potential needs to be estimated with the current maintained constant. Now, there is a problem in that even when the current is constant, the potential step of the anode cannot be detected due to characteristics of the electrode, when current value is great. This tendency is more pronounced in lithium iron phosphate (LFP) batteries than in ternary batteries.

Accordingly, an object of the present disclosure is to estimate power storage amount in a secondary battery by detecting change in the stage of the anode in the secondary battery, without depending on voltage detection.

The present disclosure relates to a power storage amount estimating device for a secondary battery, the power storage amount estimating device including a temperature acquisition unit for acquiring a temperature change during charging or discharging of the secondary battery, a change determining unit for determining whether a change rate of the temperature change varied, and a power storage amount estimating unit that, when determination is made that the change rate of the temperature change varied, estimates that a power storage amount of the secondary battery reached a predetermined power storage amount.

According to the present disclosure, the power storage amount of the secondary battery can be estimated by detecting change in the stage of the anode in the secondary battery, without depending on voltage detection.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram for explaining the entire configuration of an electrified vehicle according to the present embodiment;

FIG. 2 is a flow chart for explaining the process of EVECU shown in FIG. 1;

FIG. 3 is a diagram for explaining charge/discharge characteristics of the battery pack shown in FIG. 1;

FIG. 4 is a diagram for explaining a power storage amount when the battery pack shown in FIG. 1 is aged;

FIG. 5 is a diagram for explaining a relationship between a power storage amount in a battery cell and a temperature;

FIG. 6 is a flow chart for describing the process of EVECU shown in FIG. 1; and

FIG. 7 is a flow chart for explaining the process of EVECU shown in FIG. 1.

### DETAILED DESCRIPTION OF EMBODIMENTS

Hereinafter, the present embodiment will be described with reference to the accompanying drawings. In order to facilitate understanding of the description, the same components are denoted by the same reference numerals as much as possible in the drawings, and redundant description will be omitted.

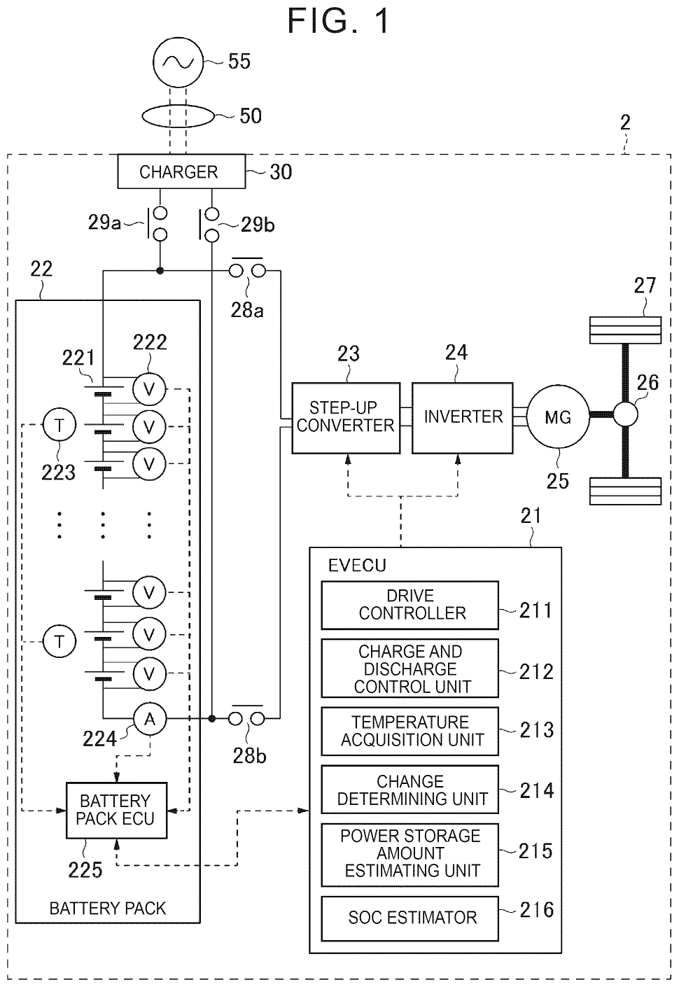

FIG. 1 is a schematic configuration diagram for explaining the entire configuration of an electrified vehicle 2 according to the present embodiment. In the present embodiment, a case where electrified vehicle 2 is battery electric vehicle (BEV: Battery Electric Vehicle) will be described. However, electrified vehicle 2 is not limited to being BEV, and may be, for example, plug-in hybrid electric vehicle (PHEV: Plug-in Hybrid Electric Vehicle), hybrid electric vehicle (HEV: Hybrid Electric Vehicle), fuel cell electric vehicle (FCEV: Fuel Cell Electric Vehicle), or the like.

Electrified vehicle 2 includes EVECU (EVECU: Electric Vehicle Electronic Control Unit) 21, a battery pack 22, a step-up converter 23, an inverter 24, a motor generator 25, a transmission gear 26, and drive wheels 27.

The battery pack 22 is mounted on electrified vehicle 2 as a driving power source that is a power source of electrified vehicle 2. The battery pack 22 is configured by stacking a plurality of cells 221 that are unit cells and connecting them in series with each other. The cell 221 is constituted by a rechargeable, for example, iron phosphate-based lithium-ion battery (LFP battery). The plurality of cells 221 may be stacked to form a cell stack, and the plurality of cell stacks may be connected in series to form the battery pack 22.

Further, a current sensor 224, a temperature sensor 223, a voltage sensor 222, and a battery pack ECU (Electric Vehicle Electronic Control Unit) 225 are disposed in the battery pack 22.

The current sensor 224 detects a battery current Ib that is an input/output current for the plurality of cells 221. The temperature sensor 223 detects a battery temperature Tb that is the temperature of the plurality of cells 221. Note that a plurality of temperature sensors 223 may be arranged so that the temperatures of the plurality of cells 221 can be accurately measured. The voltage sensor 222 detects a battery voltage Vb which is a voltage between terminals of each of the plurality of cells 221. In the present embodiment, the same number of voltage sensors 222 as the plurality of cells 221 are arranged.

The battery pack ECU 225 receives the detected values outputted by the current sensor 224, the temperature sensor 223, and the voltage sensor 222. These include the battery current Ib, the battery temperature Tb, and the battery voltage Vb. The battery pack ECU 225 outputs the battery voltage Vb, the battery current Ib, and the battery temperature Tb to EVECU 21.

The battery pack 22 is connected to the step-up converter 23 through the system main relay 28a, 28b. The step-up converter 23 boosts the output voltage of the battery pack 22. The step-up converter 23 is connected to the inverter 24. The inverter 24 converts the DC power from the step-up converter 23 into AC power.

The motor generator (three-phase AC motor) 25 receives AC power from the inverters 24 and generates kinetic energy for driving electrified vehicle 2. The kinetic energy generated by the motor generator 25 is transmitted to the drive wheels 27. On the other hand, when electrified vehicle 2 is decelerated or electrified vehicle 2 is stopped, the motor generator 25 converts the kinetic energy of electrified vehicle 2 into electric energy. The AC power generated by the motor generator 25 is converted into DC power by the inverter 24 and supplied to the battery pack 22 through the step-up converter 23. Thus, the regenerative electric power can be stored in the battery pack 22. As described above, the motor generator 25 is configured to generate the driving force or the braking force of the vehicle with the transfer of electric power to and from the battery pack 22.

Note that the step-up converter 23 can be omitted. When a DC motor is used as the motor generator 25, the inverter 24 can be omitted.

When an electrified vehicle 2 is configured as a PHEV in which an engine is further mounted as a power source, the output of the engine can be used as a driving force for traveling in addition to the output of the motor generator 25. It is also possible to generate the charging power of the battery pack 22 by the engine output using a motor generator that generates power by the engine output.

Electrified vehicle 2 has an external charging function for charging the battery pack 22 by the external power source 55. Electrified vehicle 2 includes a charger 30 and a charge-relay 29a, 29b. In the present disclosure, charging of the battery pack 22 using the external power source 55 is referred to as “external charging”.

The external power source 55 is a power supply provided outside the vehicle, and is, for example, a commercial power supply. The charger 30 converts the electric power from the external power source 55 into the charging electric power of the battery pack 22. The charger 30 is connected to the battery pack 22 through a charge-relay 29a, 29b. When the charge-relay 29a, 29b is on, the battery pack 22 can be charged by electric power from the external power source 55.

The external power source 55 and the charger 30 can be connected by, for example, a charging cable 50. When the charging cable 50 is connected to the external power source 55, the external power source 55 and the charger 30 are electrically connected to each other, and the battery pack 22 can be charged using the external power source 55. Alternatively, electrified vehicle 2 may be configured to transmit power between the external power source 55 and the charger 30 in a contactless manner. For example, the battery pack 22 can be charged by the external power source 55 by transmitting electric power through a power transmission coil (not shown) on the external power source side and a power reception coil (not shown) on electrified vehicle side.

When AC power is supplied from the external power source 55, the charger 30 is configured to have a function of converting the supply power (AC power) from the external power source 55 into the charging power (DC power) of the battery pack 22. When the external power source 55 is a DC power supply, the charger 30 adjusts the magnitude of the DC power from the external power source 55 and supplies the adjusted DC power to the battery pack 22. The mode of external charging of electrified vehicle 2 is not particularly limited.

EVECU 21 includes, as electric components, a microcomputer (hereinafter, also referred to as a microcomputer), a data-transfer circuit, a power supply circuit, and a power supply detecting circuit. The microcomputer includes a CPU (Central Processing Unit), ROM (Read Only Memory), RAM (Random Access Memory), and a flash memory. EVECU 21 includes, as functional components, a drive control unit 211, a charge and discharge control unit 212, a temperature acquisition unit 213, a change determining unit 214, a power storage amount estimating unit 215, and a SOC estimating unit 216. EVECU 21 receives a signal outputted from various sensors such as a throttle valve opening degree sensor (not shown) and a vehicle speed sensor (not shown), and an on/off signal corresponding to an operation of a power switch (not shown) for starting/stopping.

The drive control unit 211 executes various calculations based on various types of signals inputted to EVECU 21, and controls operations of various devices such as the step-up converters 23, the inverters 24, and the system main relay 28a, 28b. When a power switch (not shown) is switched from off to on, the drive control unit 211 switches the system main relay 28a, 28b from off to on, and operates the step-up converter 23 and the inverter 24. When a power switch (not shown) is switched from on to off, the drive control unit 211 switches the system main relay 28a, 28b from on to off, and stops the step-up converter 23 and the inverter 24.

The charge and discharge control unit 212 controls the charger 30 and the charge-relay 29a, 29b to perform external charging of the battery pack 22. When the start switch (power switch) is switched from off to on, the charge and discharge control unit 212 switches the system main relay 28a, 28b from off to on.

The temperature acquisition unit 213 is a portion that acquires a temperature change during discharging or charging of the battery pack 22. The temperature acquisition unit 213 acquires a temperature change during discharging or charging of the battery pack 22 based on the battery temperature Tb outputted from the battery pack ECU 225. The temperature acquisition unit 213 also acquires the ambient temperature of the area in which the battery pack 22 is disposed. The ambient temperature may be acquired from an ambient temperature sensor (not shown) or may be estimated from weather data.

The change determining unit 214 is a portion that determines whether or not the rate of change in temperature during discharge or charging of the battery pack 22 is equal to or greater than a predetermined rate of change. The power storage amount estimating unit 215 is a portion that estimates the power storage amount of the battery pack 22 when the rate of change in temperature during discharge or charging of the battery pack 22 becomes equal to or greater than a predetermined rate of change. SOC estimation unit 216 estimates SOC (State Of Charge of the battery pack 22).

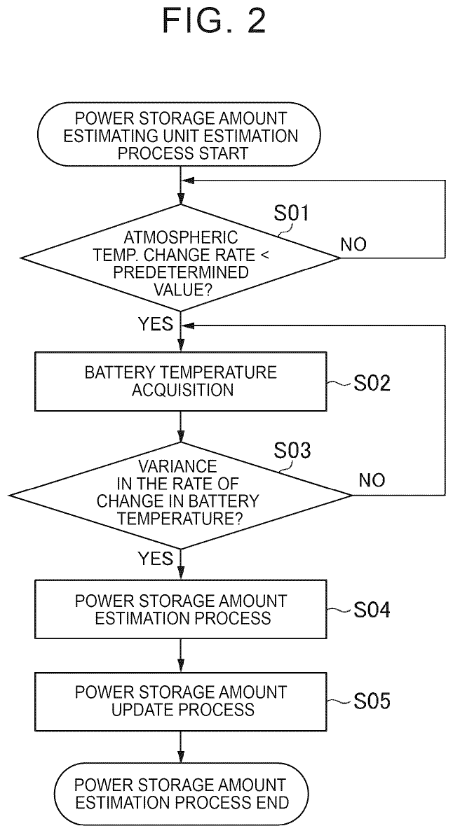

Next, referring to FIG. 2, a power storage amount estimation procedure in EVECU 21 will be described. In FIG. 2, the processing at the time of charging is described as an example, but it is possible to perform the estimation processing similarly at the time of discharging. In S01, the temperature acquisition unit 213 acquires the ambient temperature, and determines whether or not the ambient temperature change rate is less than a predetermined value. This is because the power storage amount is estimated based on the temperature change of the batteries after S02, so that the change in the ambient temperature does not affect the judgment.

If the rate of change of the ambient temperature is less than the predetermined value (S01: YES), the processing proceeds to S02. If the rate of change of the ambient temperature is not less than the predetermined value (S01: NO), S01 process is repeated.

In S02, the temperature acquisition unit 213 acquires the battery temperature Tb of the battery pack 22. The temperature acquisition unit 213 continues to acquire the battery temperature Tb at predetermined time-intervals. In S03 following S02, the temperature acquisition unit 213 determines whether or not there is a variance in the rate of change of the battery temperature Tb.

If the rate of change of the battery temperature Tb varies (S03: YES), processing proceeds to S04. If the rate of change of the battery temperature Tb does not vary (S03: NO), processing proceeds to S02.

In S04, the power storage amount estimating unit 215 estimates the power storage amount of the battery pack 22. In S05 following S04, the power storage amount estimating unit 215 performs a process of updating the power storage amount of the battery pack 22. This power storage amount may be used as an amount of electric power that can be discharged by the battery pack 22, and may be used for calculation of a travelable distance or the like.

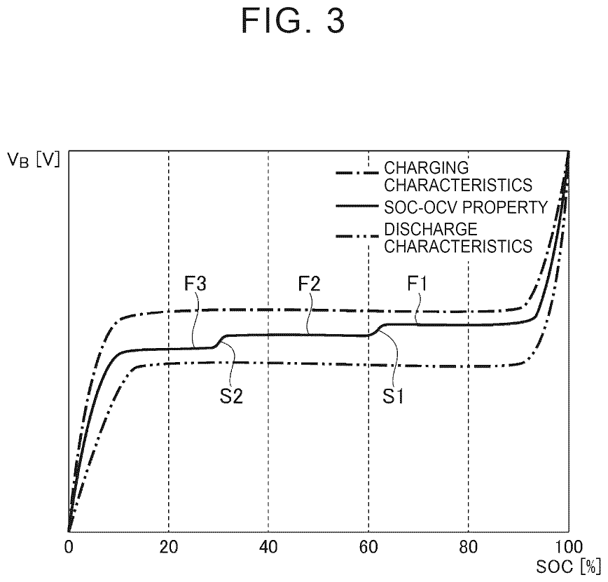

Next, a method of estimating the power storage amount of the battery pack 22 by the power storage amount estimating unit 215 will be described with reference to FIGS. 3, 4, and 5.

FIG. 3 is a diagram illustrating charge-discharge characteristics of a secondary battery as an example. In FIG. 3, the vertical axis represents the battery voltage VB, and the horizontal axis represents SOC. In FIG. 3, the solid line exemplifies SOC-OCV properties of the secondary batteries. The dashed-dotted lines illustrate the charge properties (charge curves) when charged at high currents (e.g., charge rates: 2C). The two-dot chain line exemplifies a discharge characteristic (discharge curve) when discharging at a large current (for example, discharge rate: 2C).

SOC-OCV property is a function of OCV and SOC, which are the discharge pressures of batteries. In some secondary batteries, as shown in FIG. 3, the first stage change S1 and the second stage change S2 clearly appear, and the first flat region F1, the second flat region F2, and the third flat region F3 can be clearly recognized. However, when the charge/discharge current is large, a steep change in the battery voltage VB may not appear at the time of the change of stages, such as the one-dot chain line and the two-dot chain line shown in FIG. 3.

In addition, in some secondary batteries, a clear change in stages as shown in FIG. 3 cannot be recognized even in SOC-OCV properties. In any case, it may not be possible to estimate an accurate SOC only by measuring the battery voltage VB.

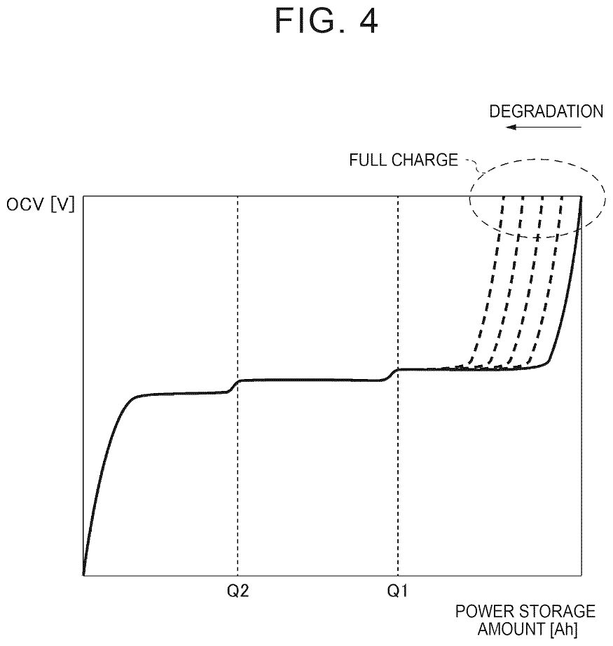

Incidentally, SOC is expressed as a ratio of the actual power storage amount to the power storage amount at the time of full charge. Although the power storage amount at the time of full charge varies due to deterioration of the secondary battery, the relationship between the change in the power storage amount at the time of full charge and the change in the stage will be described with reference to FIG. 4.

FIG. 4 is a diagram illustrating a relation between OCV and power storage amount in an exemplary secondary battery. In FIG. 4, the vertical axis represents OCV, and the horizontal axis represents the power storage amount [Ah]. In FIG. 4, the solid line exemplifies the relation between OCV and the power storage amount when the secondary batteries are new. The broken line exemplifies the relation between OCV and the power storage amount when the secondary batteries are deteriorated. As shown in FIG. 4, even if the secondary battery is deteriorated and the power storage amount (full charge capacity) at the time of full charge is lowered, the power storage amount Q1, Q2 at the time of stage change does not change, and becomes substantially the same at the time of new and deteriorated.

In the present embodiment, even if the battery pack 22 deteriorates, the power storage amount at the time of stage change is substantially the same value, and the power storage amount at the time of stage change is estimated. However, as described with reference to FIG. 3, it is not possible to grasp the change in the stages of the battery pack 22 only by measuring the battery voltage VB. Therefore, in the present embodiment, attention is paid to the temperature change of the battery pack 22, and the estimation of the stage change is performed by using the fact that the maximum value behavior of the temperature change corresponds to the stage change.

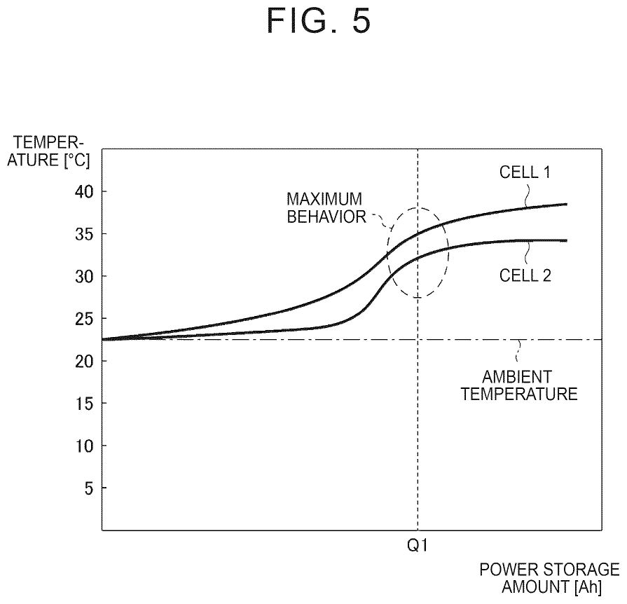

FIG. 5 is a diagram showing the relationship between the temperature and the power storage amount in the cells 221 constituting the battery pack 22. In FIG. 5, the vertical axis represents the temperature [° C.] of the cell 221, and the horizontal axis represents the power storage amount [Ah]. In FIG. 5, temperature changes are shown for the cells 1 and 2 included in the cells 221 constituting the battery pack 22 as examples.

As shown in FIG. 5, although the temperature behaviors of the cell 1 and the cell 2 do not completely coincide with each other, the temperature change rate changes in a place corresponding to the power storage amount Q1, and the maximum behavior is shown. Therefore, the power storage amount estimating unit 215 determines that the power storage amount at that time corresponds to the power storage amount Q1 if the change rate of the battery temperature Tb in S03 varies based on the determination of whether or not there is a change rate of the battery temperature Tb in S03. Therefore, the power storage amount estimating unit 215 determines that the power storage amount at that time corresponds to the first stage change S1.

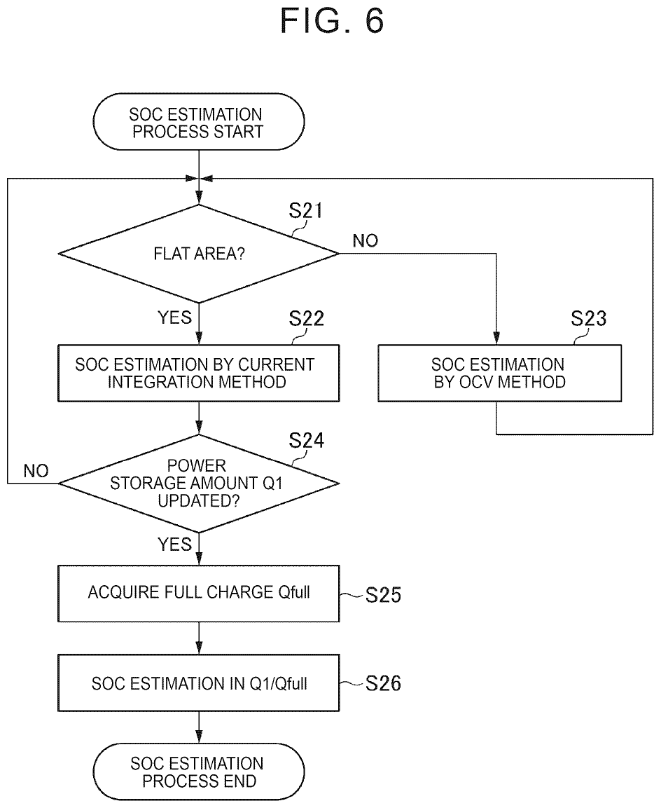

Next, referring to FIG. 6, a SOC estimation procedure in EVECU 21 will be described. In S21, SOC estimation unit 216 determines whether or not the relation between SOC and the battery voltage VB is a flat area. The relation between SOC and the cell voltage VB is, for example, between the first flat region F1 and the third flat region F3 in FIG. 3. For example, in the example of FIG. 3, the relation between SOC and the cell voltage VB is not a flat region, which is a side having a smaller SOC than the third flat region F3 or a side having a larger SOC than the first flat region F1. That is, the relationship between SOC and the battery voltage VB is not a flat area when the relationship between SOC and the battery voltage VB is a steep slope.

If the relation between SOC and the battery voltage VB is a flat area (S21: YES), processing proceeds to S22. If the relation between SOC and the battery voltage VB is not a flat area (S21: NO), processing proceeds to S23.

In S22, SOC estimation unit 216 estimates SOC of the battery pack 22 by the current integration method. When S22 process is finished, the process proceeds to S24. In S23, SOC estimation unit 216 estimates SOC of the battery pack 22 by OCV method. When S23 process is finished, the process proceeds to S21.

In S24, SOC estimation unit 216 determines whether or not the power storage amount Q1 has been updated. The updating of the power storage amount Q1 is an updating of the power storage amount Q1 performed by the power storage amount estimating unit 215 in S05 of FIG. 2.

If the power storage amount Q1 is updated (S24: YES), the processing proceeds to S25. If the power storage amount Q1 is not updated (S24: NO), the processing proceeds to S21.

In S25, SOC estimation unit 216 acquires the full charge Qfull. As described with respect to FIG. 4, since the full charge amount is decreased in accordance with the degradation of the battery pack 22, the full charge amount Qfull is the full charge amount of the battery pack 22 updated most recently.

In S25 subsequent S26, SOC estimation unit 216 calculates the power storage amount Q1/full charge amount Qfull and estimates the current SOC.

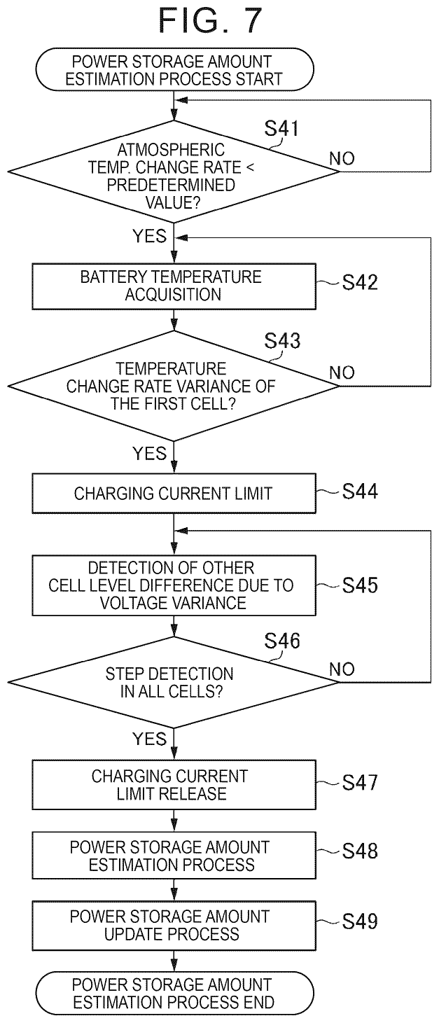

Next, referring to FIG. 7, another exemplary power storage amount estimation procedure in EVECU 21 will be described. In FIG. 7, the processing at the time of charging is described as an example, but it is possible to perform the estimation processing similarly at the time of discharging. In S41, the temperature acquisition unit 213 acquires the ambient temperature, and determines whether or not the ambient temperature change rate is less than a predetermined value.

If the rate of change of the ambient temperature is less than the predetermined value (S41: YES), the processing proceeds to S42. If the rate of change of the ambient temperature is not less than the predetermined value (S41: NO), S41 process is repeated.

In S42, the temperature acquisition unit 213 acquires the battery temperature Tb of the battery pack 22. Since a plurality of temperature sensors 223 are provided in the battery pack 22, the temperature acquisition unit 213 acquires battery temperature Tb from the temperature sensors 223. The temperature acquisition unit 213 continues to acquire the battery temperature Tb at predetermined time-intervals.

In S43 following S42, the temperature acquisition unit 213 determines whether or not the rate of change of the battery temperature Tb has varied in the first cell 221. As described above, the battery pack 22 is provided with a plurality of temperature sensors 223. The temperature change of the plurality of cells 221 is not uniform, and the behavior of the temperature change differs depending on, for example, the place where the cells 221 are arranged. The location where the temperature sensor 223 is provided is such a location as to represent a temperature change of the plurality of cells 221. Therefore, if there is a variance in the temperature change rate among the battery temperature Tb outputted from the plurality of temperature sensors 223, it is determined that there is a variance in the change rate of the battery temperature Tb in the first cell 221.

If there is a variance in the rate of change of the cell Tb in the first cell 221 (S43: YES), processing proceeds to S44. If the rate of change of the battery temperature Tb does not vary (S43: NO), processing proceeds to S42.

In S44, the charge and discharge control unit 212 limits the charge current to the battery pack 22. The charge and discharge control unit 212 limits the charging current to such an extent that a voltage step in the cells 221 constituting the battery pack 22 can be detected. The voltage step is a voltage variance that can specify a stage change in the anode of the cell 221.

In a S45 subsequent to S44, the power storage amount estimating unit 215 performs a process of detecting a voltage step in a cell 221 constituting the battery pack 22 other than the cell 221 in which a temperature change is detected in S43.

In S46 following S45, the power storage amount estimating unit 215 determines whether or not a voltage step has been detected in all the cells 221 constituting the battery pack 22 (except for the cell 221 in which a temperature change has been detected in S43).

If a voltage step is detected (S46: YES) in all the cells 221 constituting the battery pack 22 (except for the cell 221 in which a temperature change is detected in S43), the processing proceeds to S47. If no voltage step is detected (S46: NO) in all the cells 221 constituting the battery pack 22 (except for the cell 221 in which a temperature change is detected in S43), the process proceeds to S45. In S47, the charge and discharge control unit 212 cancels the process of limiting the charge current to the battery pack 22.

In S48 following S47, the power storage amount estimating unit 215 estimates the power storage amount of the battery pack 22. In estimating the power storage amount in S48, the power storage amount is estimated based on the estimated power storage amount in each cell 221. This estimation is performed by appropriately performing numerical processing such as an average value or a median value of the power storage amounts in the individual cells 221. In S49 following S48, the power storage amount estimating unit 215 performs a process of updating the power storage amount of the battery pack 22.

The present embodiment has been described above with reference to specific examples. However, the present disclosure is not limited to these specific examples. Those skilled in the art with appropriate design modifications to these specific examples are also included in the scope of the present disclosure as long as they include the features of the present disclosure. Each element included in each of the above-described specific examples and the arrangement, condition, shape, and the like thereof are not limited to those illustrated, and can be appropriately changed. Each element included in each of the above-described specific examples can be appropriately combined and changed as long as there is no technical inconsistency.

### Additional Remarks

The following supplementary notes 1 to 3 can be arbitrarily combined as long as they are not technically contradictory.

### Appendix 1

A power storage amount estimating device for a secondary battery, comprising:
A temperature acquisition unit 213 for acquiring a temperature change during charging or discharging of the secondary battery,
A change determining unit 214 for determining whether or not the change rate of the temperature change has varied,
The power storage amount estimating unit 215 estimates that the power storage amount of the secondary battery becomes the predetermined power storage amount when it is determined that the change rate of the temperature change has varied.

In the present embodiment, the battery pack 22 and the cell 221 are exemplified as the secondary battery. The cell 221 is exemplified by a LFP cell, but may be a so-called ternary cell. It is preferable to use a secondary battery having a SOC-OCV property having a flat area in which the rate of change of the open-end voltage with respect to the storage rate is equal to or less than a predetermined value. Although a EVECU 21 is exemplified as the power storage amount estimating device in the present embodiment, other ECU may be used as long as they can function as the power storage amount estimating device, and the power storage amount estimating device may be configured by a plurality of ECU.

According to Appendix 1, when it is determined that the change rate of the temperature change varied, it is estimated that the power storage amount of the secondary battery becomes the predetermined power storage amount, so that it is possible to detect the change in the stage of the anode regardless of the voltage detection, and thus it is possible to estimate the power storage amount of the secondary battery.

### Appendix 2

The power storage amount estimating device according to Appendix 1, The change determining unit 214 determines that the change rate of the temperature change varies when the change rate of the temperature change indicates the endothermic reaction of the secondary battery.

As described with reference to FIG. 5, when the battery pack 22 and the cell 221 are charged, an endothermic reaction occurs in the vicinity of Q1 where the power storage amount is about 60%, and the rate of change in temperature exhibits a maximum value behavior. On the other hand, in the vicinity of Q2 where the power storage amount is about 30% (see FIG. 4), the exothermic reaction occurs, and the rate of change in temperature does not show the maximum value behavior. According to Appendix 2, it is possible to accurately detect a Q1 that is a predetermined power storage amount, and the system for estimating the power storage amount of the secondary battery is improved.

### Appendix 3

The power storage amount estimating device according to Appendix 1 or 2,
A charge and discharge control unit 212 for controlling charging and discharging of the secondary battery is further provided.
A plurality of secondary batteries are provided and connected in series,
After the change determining unit 214 detects the change rate of the temperature change of the first secondary battery, the charge and discharge control unit 212 limits the charge and discharge currents of the other secondary batteries.
The power storage amount estimating unit 215 detects voltage steps in a plurality of secondary batteries, and estimates the power storage amount based on the detected voltage steps.

According to Appendix 3, after the change rate of the temperature change of the first secondary battery is detected, the charge and discharge control unit 212 limits the charge/discharge current of the other secondary battery, so that the charge/discharge current is reduced and the voltage level difference is easily detected in the other secondary battery. Since the power storage amount estimating unit 215 detects the voltage level difference in the plurality of secondary batteries and estimates the power storage amount based on the detected voltage level difference, the estimation accuracy of the power storage amount is improved.

What is claimed is:

1. A power storage amount estimating device for a secondary battery, the power storage amount estimating device comprising:
a temperature acquisition unit for acquiring a temperature change during charging or discharging of the secondary battery;
a change determining unit for determining whether a change rate of the temperature change varied; and
a power storage amount estimating unit that, when determination is made that the change rate of the temperature change varied, estimates that a power storage amount of the secondary battery reached a predetermined power storage amount.

2. The power storage amount estimating device according to claim 1, wherein the change determining unit determines that the change rate of the temperature change varied when the change rate of the temperature change indicates an endothermic reaction of the secondary battery.

3. The power storage amount estimating device according to claim 1, further comprising:
a charge and discharge control unit for controlling charging and discharging of the secondary battery, wherein
a plurality of the secondary battery is provided and also connected in series,
after the change determining unit detects the change rate of the temperature change of a first secondary battery, the charge and discharge control unit limits a charging and discharging current another of the secondary batteries, and
the power storage amount estimating unit detects a voltage step in the secondary batteries, and estimates the power storage amount based on the voltage step that is detected.
